(19) United States
(12) Patent Application Publication
(10) Pub. No.: US 2025/0285848 A1
(43) Pub. Date: Sep. 11, 2025

(54) PLASMA ANALYSIS DEVICE, PLASMA ANALYSIS METHOD, AND SUBSTRATE PROCESSING APPARATUS

(71) Applicant: SEMES CO., LTD., Cheonan-si (KR)

(72) Inventors: Hyun Cheol CHO, Cheonan-si (KR); Myeong Jun LIM, Cheonan-si (KR); Kwang Sup KIM, Cheonan-si (KR)

(73) Assignee: SEMES CO., LTD., Cheonan-si (KR)

(21) Appl. No.: 19/069,693

(22) Filed: Mar. 4, 2025

(30) Foreign Application Priority Data
Mar. 5, 2024 (KR) 10-2024-0031412

(51) Int. Cl. H01J 37/32

(52) U.S. Cl. CPC H01J 37/32935; H01J 37/3299; H01J 2237/221; H01J 2237/24542

(57) ABSTRACT

Disclosed are a plasma analysis device and a plasma analysis method capable of analyzing the uniformity of plasma formed in a process chamber. The device for analyzing plasma in a substrate processing apparatus for processing a substrate using plasma includes an optical system configured to adjust the path of light incident thereon from a process chamber in which the substrate is processed, a camera configured to capture an image of plasma formed in the process chamber, and an image analyzer configured to analyze the form of the plasma using the image of the plasma captured by the camera. The camera captures an image containing a plasma shape in horizontal directions parallel to the placement directions of the substrate. The image analyzer evaluates the uniformity of the plasma shape in the image.

### CROSS-REFERENCE TO THE RELATED APPLICATION

The present application claims priority to and the benefit of Korean Patent Application No. 10-2024-0031412, filed on Mar. 5, 2024, in the Korean Intellectual Property Office, the entire disclosure of which is incorporated herein by reference.

### BACKGROUND

### 1. Field

The present disclosure relates to a substrate processing apparatus for processing a substrate using plasma, and more particularly, to a plasma analysis device, a plasma analysis method, and a substrate processing apparatus including the plasma analysis device.

### 2. Description of the Related Art

A semiconductor (or display) manufacturing process is a process for manufacturing a semiconductor device on a substrate (e.g., a wafer), and includes, for example, exposure, deposition, etching, ion implantation, and cleaning. In order to perform each manufacturing process, semiconductor manufacturing equipment that performs each process is provided in a clean room of a semiconductor manufacturing plant, and each process is performed on a substrate loaded in the semiconductor manufacturing equipment.

Processes using plasma, for example, etching and deposition, are widely used in the semiconductor manufacturing process. A plasma processing process is performed in such a manner that a substrate is seated at a lower portion in a chamber defining a plasma processing space, process gas for plasma processing is supplied, and power is applied via electrodes located at an upper portion and a lower portion in the chamber.

A substrate processing process is greatly influenced by distribution of plasma in a process chamber. Therefore, a method of measuring distribution of plasma in order to improve the distribution characteristics of plasma is employed. In particular, in order to achieve a uniform etch rate over the entire area of a substrate in a dry etching process, plasma needs to be uniformly formed over the entire area of the substrate. In order to achieve uniform formation of plasma, it is required to analyze the current state of the plasma in the process chamber.

### SUMMARY

The present disclosure provides a plasma analysis device, a plasma analysis method, and a substrate processing apparatus capable of analyzing the uniformity of plasma formed in a process chamber.

According to an embodiment of the present disclosure, a device for analyzing plasma in a substrate processing apparatus for processing a substrate using plasma includes an optical system configured to adjust the path of light incident thereon from a process chamber in which the substrate is processed, a camera configured to capture an image of plasma formed in the process chamber, and an image analyzer configured to analyze the form of the plasma using the image of the plasma captured by the camera. The camera captures an image containing a plasma shape in horizontal directions parallel to the placement directions of the substrate, and the image analyzer evaluates the uniformity of the plasma shape in the image.

In the embodiment of the present disclosure, the optical system may be implemented as a view port formed in the wall of the process chamber, and the camera may capture the image through the optical system.

In the embodiment of the present disclosure, the image analyzer may compare the plasma shape with center lines of the image to evaluate the uniformity of the plasma shape.

In the embodiment of the present disclosure, the image analyzer may evaluate the uniformity of the plasma shape based on a distance between the center point of gravity of the plasma shape and the image center point at which the center lines perpendicularly intersect each other.

In the embodiment of the present disclosure, the image analyzer may evaluate the uniformity of the plasma shape based on ratios of areas of portions of the plasma shape to respective areas of the image divided by the center lines.

In the embodiment of the present disclosure, the optical system may adjust the path of light to allow the camera to capture an image containing a plasma shape in horizontal directions parallel to the placement directions of the substrate.

In the embodiment of the present disclosure, the camera may comprise a polarizing filter configured to block electromagnetic waves generated from the plasma.

According to another embodiment of the present disclosure, a plasma analysis method performed by the plasma analysis device in a substrate processing apparatus for processing a substrate using plasma includes capturing, by the camera, an image containing a plasma shape in horizontal directions parallel to the placement directions of the substrate and evaluating, by the image analyzer, the uniformity of the plasma shape in the image.

According to still another embodiment of the present disclosure, an apparatus for processing a substrate using plasma includes a process chamber in which the substrate is processed and a plasma analysis device configured to analyze the uniformity of plasma formed in the process chamber. The plasma analysis device includes an optical system configured to adjust the path of light incident thereon from the process chamber, a camera configured to capture an image of plasma formed in the process chamber, and an image analyzer configured to analyze the form of the plasma using the image of the plasma captured by the camera.

### BRIEF DESCRIPTION OF THE DRAWINGS

The accompanying drawings, which are incorporated in this specification, illustrate exemplary embodiments and serve to further illustrate the technical ideas of the disclosure in conjunction with the detailed description of exemplary embodiments that follows, and the disclosure is not to be construed as limited to what is shown in such drawings. In the drawings:

FIG. 1 shows the structure of a substrate processing apparatus to which a plasma analysis device according to the present disclosure is applied;

FIG. 2 shows an example of an image containing a plasma shape;

FIG. 3 shows examples of an image containing the shape of plasma formed non-uniformly;

FIGS. 4 and 5 are views for explaining a process of evaluating the uniformity of plasma; and

FIG. 6 is a flowchart showing a plasma analysis method performed by the plasma analysis device according to the present disclosure.

### DETAILED DESCRIPTION OF EXEMPLARY EMBODIMENTS

Hereinafter, embodiments of the present disclosure will be described in detail with reference to the accompanying drawings so that those skilled in the art can easily carry out the embodiments. The present disclosure may, however, be embodied in many different forms, and should not be construed as being limited to the embodiments set forth herein.

Parts irrelevant to description of the present disclosure will be omitted to clearly describe the present disclosure, and the same or similar constituent elements will be denoted by the same reference numerals throughout the specification.

In addition, constituent elements having the same configurations in several embodiments will be assigned with the same reference numerals and described only in the representative embodiment, and only constituent elements different from those of the representative embodiment will be described in the other embodiments.

Throughout the specification, when a constituent element is said to be “connected”, “coupled”, or “joined” to another constituent element, the constituent element and the other constituent element may be “directly connected”, “directly coupled”, or “directly joined” to each other, or may be “indirectly connected”, “indirectly coupled”, or “indirectly joined” to each other with one or more intervening elements interposed therebetween. In addition, throughout the specification, when a constituent element is referred to as “comprising”, “including”, or “having” another constituent element, the constituent element should not be understood as excluding other elements, so long as there is no special conflicting description, and the constituent element may include at least one other element.

Unless otherwise defined, all terms used herein, which include technical or scientific terms, have the same meanings as those generally appreciated by those skilled in the art. The terms, such as ones defined in common dictionaries, should be interpreted as having the same meanings as terms in the context of pertinent technology, and should not be interpreted as having ideal or excessively formal meanings unless clearly defined in the specification.

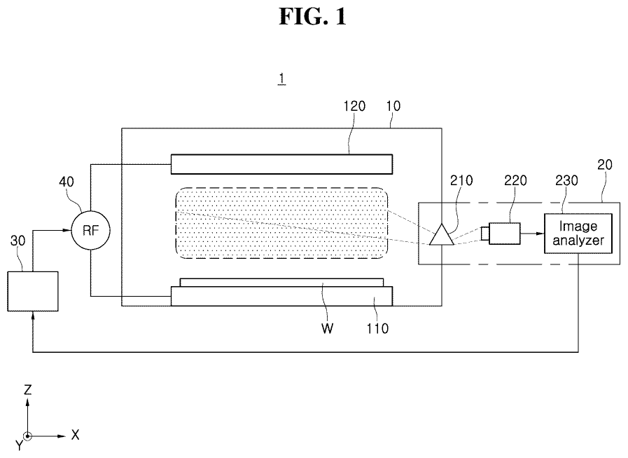

FIG. 1 shows the structure of a substrate processing apparatus 1 to which a plasma analysis device 20 according to the present disclosure is applied. FIG. 1 is a cross-sectional view of the substrate processing apparatus 1 when viewed from the side. In FIG. 1, horizontal directions X and Y are directions in which a substrate W is placed. The first horizontal direction X and the second horizontal direction Y are orthogonal to each other. A vertical direction Z is a direction orthogonal to the horizontal directions X and Y, and refers to a direction perpendicular to the plane on which the substrate W is placed.

The substrate processing apparatus 1 processes the substrate W using plasma. The substrate processing apparatus 1 includes a process chamber 10, a plasma analysis device 20, a radio-frequency (RF) controller 30, and an RF power supply 40. Although not shown in FIG. 1, the substrate processing apparatus 1 may further include a gas supply unit configured to supply gas to the interior of the process chamber 10 and an exhaust unit configured to discharge gas from the process chamber 10.

The process chamber 10 is a structure defining a space in which the substrate W is processed. The process chamber 10 is provided therein with a substrate support 110, on which the substrate W is seated and which functions as a lower electrode, and an upper electrode 120.

The substrate support 110 supports the substrate W from below. The substrate support 110 may be provided as an electrostatic chuck (ESC) that chucks the substrate W using electrostatic force. A heater for control of temperature of the substrate W and a refrigerant path through which refrigerant flows may be provided in the substrate support 110. In addition, a flow path for supplying an inert gas (e.g., helium) so that temperature is uniformly transmitted to the entire area of the substrate W may be formed in the substrate support 110. In addition, the substrate support 110 may be connected to the RF power supply 40 to receive RF power for generation of plasma.

The upper electrode 120 is located in an upper space in the process chamber 10. The upper electrode 120 may be connected to the RF power supply 40 to receive RF power for generation of plasma. The upper electrode 120 may be an antenna composed of at least one coil. Alternatively, the upper electrode 120 may be a showerhead that sprays a process gas to the interior of the process chamber 10. One of the upper electrode 120 and the substrate support 110 may be grounded, and the other thereof may be connected to the RF power supply 40 to receive RF power.

The plasma analysis device 20 photographs the shape of plasma formed in the process chamber 10, analyzes the shape of the plasma, and provides information about the uniformity of the plasma to the RF controller 30. The RF controller 30 may control the RF power supply 40 based on the plasma uniformity information received from the plasma analysis device 20. In addition, the RF controller 30 may control the output of the heater provided in the substrate support 110 based on the plasma uniformity information. The RF controller 30 may control an impedance matching circuit or a filter located between the RF power supply 40 and the substrate support 110 or the upper electrode 120. Alternatively, the RF controller 30 may control a separate RF module for control of distribution of the plasma. The RF controller 30 may control, based on the current distribution uniformity of the plasma in the process chamber 10, the RF power supply 40 such that the plasma is more uniformly distributed over the entire area of the substrate W. The RF power supply 40 supplies RF power to the substrate support 110 or the upper electrode 120 in order to generate plasma.

The plasma analysis device 20 includes an optical system 210 configured to adjust the path of light incident thereon from the process chamber 10, a camera 220 configured to capture an image of the plasma formed in the process chamber 10, and an image analyzer 230 configured to analyze the form of the plasma using the image of the plasma captured by the camera 220.

The optical system 210 forms an optical path through which light of the plasma formed in the process chamber 10 is incident on the camera 220. The optical system 210 may include at least one lens, a mirror, an optical filter, and a beam splitter. The optical system 210 may be formed in the wall of the process chamber 10. The optical system 210 may be implemented as a view port formed in the wall of the process chamber 10. The optical system 210 may adjust the optical path such that the image of the plasma is captured by the camera 220 on a horizontal plane X-Y parallel to the plane on which the substrate W is placed.

The camera 220 photographs the plasma incident thereon through the optical system 210. In particular, the camera 220 captures an image containing the shape of the plasma in the horizontal directions parallel to the directions in which the substrate W is placed. The camera 220 may include one or more image sensors, a lens, a camera controller, an image processing processor, and a flashlight.

The camera 220 may include a polarizing filter that blocks short-range electromagnetic waves generated from the plasma. Because short-range electromagnetic waves generated from the plasma are blocked by the polarizing filter included in the camera 220, it is possible to remove the influence of the short-range electromagnetic waves generated from the plasma. For example, it is possible to prevent the occurrence of noise in the image captured by the camera 220 or interference between components included in the camera 220 due to the short-range electromagnetic waves generated from the plasma.

The image analyzer 230 analyzes the form of plasma using the image of the plasma captured by the camera 220. The image analyzer 230 is a device that analyzes the characteristics of the plasma in the process chamber 10 using the image of the plasma captured by the camera 220. The image analyzer 230 may be implemented as one or more computers. The image analyzer 230 may include a processor, such as a central processing unit (CPU), a graphics processing unit (GPU), or a neural processing unit (NPU), a memory, such as a dynamic random access memory (DRAM), a solid state drive (SSD), or a hard disk drive (HDD), a communication module, such as a modem or a wireless network adapter, and input/output devices, such as a keyboard, a mouse, a monitor, and a speaker.

According to the present disclosure, the camera 220 captures an image containing the shape of the plasma in the horizontal directions parallel to the directions in which the substrate W is placed, and the image analyzer 230 evaluates the uniformity of the shape of the plasma from the image. As the image analyzer 230 evaluates the uniformity of the shape of the plasma from the image containing the shape of the plasma in the horizontal directions, the RF controller 30 may control, based on the current uniformity of the shape of the plasma, the RF power supply 40 or another device such that the plasma is uniformly distributed.

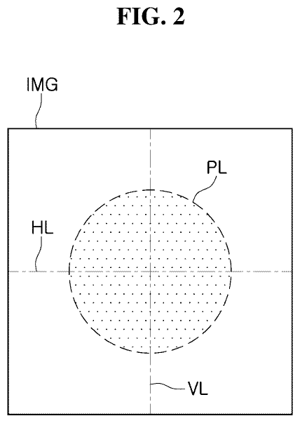

FIG. 2 shows an example of an image IMG containing a plasma shape PL. The camera 220 captures an image IMG containing the plasma shape PL through the optical system 210. After the image IMG is captured as shown in FIG. 2, the image analyzer 230 inspects whether the plasma has been normally formed based on the plasma shape PL contained in the image IMG.

The image analyzer 230 may compare the plasma shape PL with center lines HL and VL of the image IMG to evaluate the uniformity of the plasma shape PL. In the image IMG, the center lines include a horizontal center line HL and a vertical center line VL. The horizontal center line HL and the vertical center line VL are lines perpendicular to each other. The center point at which the horizontal center line HL and the vertical center line VL meet each other coincides with the center point of the substrate W. The image analyzer 230 evaluates whether the plasma shape PL is uniformly formed based on the horizontal center line HL and the vertical center line VL. As shown in FIG. 2, when the horizontal center line HL and the vertical center line VL pass through the horizontal center and the vertical center of the plasma shape PL, the image analyzer 230 may determine that the plasma has been uniformly formed in the process chamber 10.

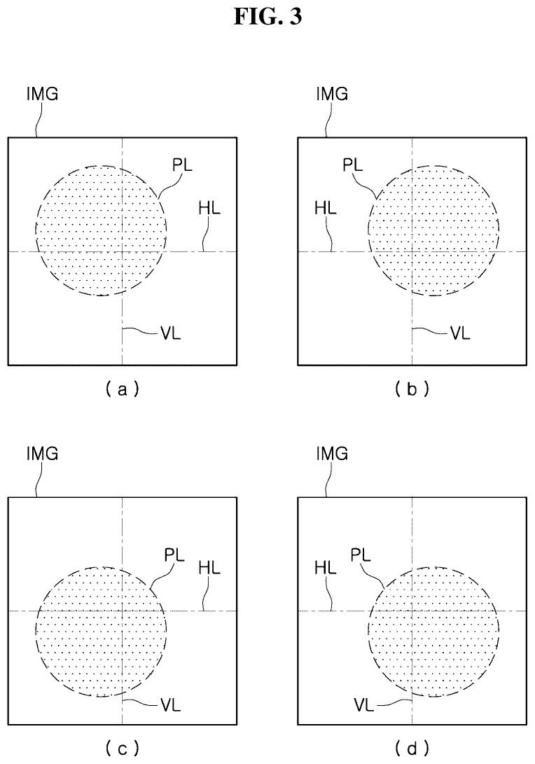

FIG. 3 shows examples of an image containing the shape of the plasma formed non-uniformly. FIG. 3(a) shows the shape PL of the plasma formed concentratively in the left-upper area of the image IMG, FIG. 3(b) shows the shape PL of the plasma formed concentratively in the right-upper area of the image IMG, FIG. 3(c) shows the shape PL of the plasma formed concentratively in the left-lower area of the image IMG, and FIG. 3(d) shows the shape PL of the plasma formed concentratively in the right-lower area of the image IMG. When the plasma shape PL is photographed as shown in FIGS. 3(a) to 3(d), the image analyzer 230 may determine that the plasma has been non-uniformly formed in the process chamber 10.

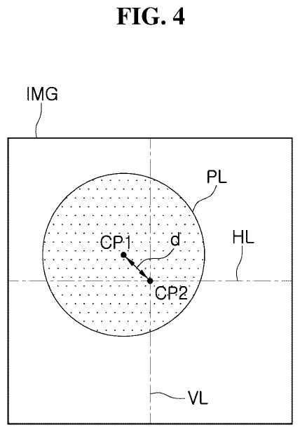

In the embodiment of the present disclosure, the image analyzer 230 may evaluate the uniformity of the plasma shape PL based on a distance d between the center point of gravity CP1 of the plasma shape PL and the image center point CP2 at which the center lines HL and VL perpendicularly intersect each other. As shown in FIG. 4, the image analyzer 230 may determine that, the greater the distance d between the center point of gravity CP1 of the plasma shape PL and the image center point CP2 at which the horizontal center line HL and the vertical center line VL intersect each other, the lower the uniformity of the plasma shape PL. The image analyzer 230 may determine that, the less (the closer to zero) the distance d between the center point of gravity CP1 of the plasma shape PL and the image center point CP2 at which the horizontal center line HL and the vertical center line VL intersect each other, the higher the uniformity of the plasma shape PL.

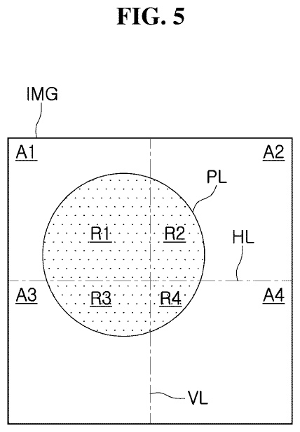

In the embodiment of the present disclosure, the image analyzer 230 may evaluate the uniformity of the plasma shape PL based on ratios of the areas R1, R2, R3, and R4 of portions of the plasma shape PL to respective areas A1, A2, A3, and A4 of the image IMG divided by the center lines HL and VL. As shown in FIG. 5, the image IMG is divided into four areas A1, A2, A3, and A4 by the horizontal center line HL and the vertical center line VL, and the areas R1, R2, R3, and R4 of four portions of the plasma shape PL occupying the four areas A1, A2, A3, and A4 of the image IMG, respectively, are calculated. The image analyzer 230 may calculate ratios of the areas R1, R2, R3, and R4 of the four portions of the plasma shape PL to the respective areas A1, A2, A3, and A4 of the image IMG divided by the center lines HL and VL. The image analyzer 230 may determine that, the larger the differences between the ratios of the areas R1, R2, R3, and R4 of the four portions of the plasma shape PL to the respective areas A1, A2, A3, and A4 of the image IMG, the lower the uniformity of the plasma shape PL. In addition, the image analyzer 230 may determine that, the smaller the differences between the ratios of the areas R1, R2, R3, and R4 of the four portions of the plasma shape PL to the respective areas A1, A2, A3, and A4 of the image IMG, that is, the more similar to each other the ratios of the areas R1, R2, R3, and R4 of the four portions of the plasma shape PL to the respective areas A1, A2, A3, and A4 of the image IMG are, the higher the uniformity of the plasma shape PL.

Through the above-described method, the image analyzer 230 may evaluate the uniformity of the plasma shape PL in the image IMG, and may transmit information about the uniformity of the plasma shape PL to the RF controller 30. The RF controller 30 may control, based on the information about the uniformity of the plasma shape PL, the RF power supply 40 or another device to change the plasma formation conditions, thereby securing uniform formation of the plasma in the process chamber 10.

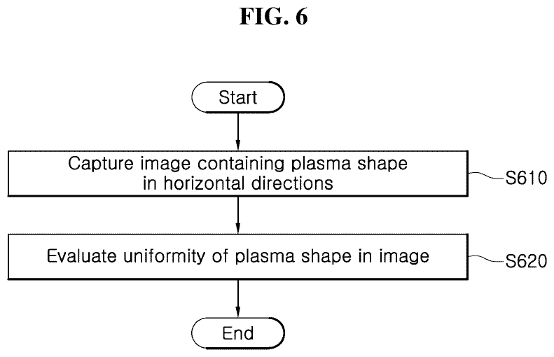

FIG. 6 is a flowchart showing a plasma analysis method performed by the plasma analysis device 20 according to the present disclosure. The plasma analysis method according to the present disclosure includes a step S610 in which the camera 220 captures an image IMG containing a plasma shape PL in the horizontal directions X and Y parallel to the directions in which the substrate W is placed and a step S620 in which the image analyzer 230 evaluates the uniformity of the plasma shape PL in the image IMG.

In the embodiment of the present disclosure, the step S620 of evaluating the uniformity of the plasma shape PL in the image IMG may include a step of comparing the plasma shape PL with the center lines HL and VL of the image IMG to evaluate the uniformity of the plasma shape PL.

In the embodiment of the present disclosure, the step S620 of evaluating the uniformity of the plasma shape PL in the image IMG may include a step of calculating a distance d between the center point of gravity CP1 of the plasma shape PL and the image center point CP2 at which the center lines HL and VL perpendicularly intersect each other to evaluate the uniformity of the plasma shape PL.

In the embodiment of the present disclosure, the step S620 of evaluating the uniformity of the plasma shape PL in the image IMG may include a step of calculating ratios of the areas R1, R2, R3, and R4 of portions of the plasma shape PL to respective areas A1, A2, A3, and A4 of the image IMG divided by the center lines HL and VL to evaluate the uniformity of the plasma shape PL.

As is apparent from the above description, according to the present disclosure, the uniformity of a plasma shape may be evaluated based on an image containing the plasma shape in horizontal directions. Accordingly, the uniformity of the plasma formed in a process chamber may be analyzed, and the plasma may be controlled based on the analyzed uniformity thereof.

Although the preferred embodiments of the present disclosure have been disclosed for illustrative purposes, those skilled in the art will appreciate that various modifications, additions and substitutions are possible, without departing from the scope and spirit of the disclosure.

The scope of the present disclosure should be defined only by the appended claims, and all technical ideas within the scope of equivalents to the claims should be construed as falling within the scope of the disclosure.

What is claimed is:

1. A device for analyzing plasma in a substrate processing apparatus for processing a substrate using plasma, the device comprising:
an optical system configured to adjust a path of light incident thereon from a process chamber in which the substrate is processed;
a camera configured to capture an image of plasma formed in the process chamber; and
an image analyzer configured to analyze a form of the plasma using an image of the plasma captured by the camera,
wherein the camera captures an image containing a plasma shape in horizontal directions parallel to placement directions of the substrate, and
wherein the image analyzer evaluates uniformity of the plasma shape in the image.

2. The device as claimed in claim 1, wherein the optical system is implemented as a view port formed in a wall of the process chamber, and
wherein the camera captures the image through the optical system.

3. The device as claimed in claim 1, wherein the image analyzer compares the plasma shape with center lines of the image to evaluate uniformity of the plasma shape.

4. The device as claimed in claim 3, wherein the image analyzer evaluates uniformity of the plasma shape based on a distance between a center point of gravity of the plasma shape and an image center point at which the center lines perpendicularly intersect each other.

5. The device as claimed in claim 3, wherein the image analyzer evaluates uniformity of the plasma shape based on ratios of areas of portions of the plasma shape to respective areas of the image divided by the center lines.

6. The device as claimed in claim 1, wherein the optical system adjusts the path of light to allow the camera to capture an image containing a plasma shape in horizontal directions parallel to placement directions of the substrate.

7. The device as claimed in claim 1, wherein the camera comprises a polarizing filter configured to block electromagnetic waves generated from the plasma.

8. A plasma analysis method performed by a plasma analysis device in a substrate processing apparatus for processing a substrate using plasma, wherein the plasma analysis device comprises:
an optical system configured to adjust a path of light incident thereon from a process chamber in which the substrate is processed;
a camera configured to capture an image of plasma formed in the process chamber; and
an image analyzer configured to analyze a form of the plasma using an image of the plasma captured by the camera, and
wherein the plasma analysis method comprises:
capturing, by the camera, an image containing a plasma shape in horizontal directions parallel to placement directions of the substrate; and
evaluating, by the image analyzer, uniformity of the plasma shape in the image.

9. The plasma analysis method as claimed in claim 8, wherein the optical system is implemented as a view port formed in a wall of the process chamber, and
wherein the camera captures the image through the optical system.

10. The plasma analysis method as claimed in claim 8, wherein evaluating uniformity of the plasma shape in the image comprises comparing the plasma shape with center lines of the image to evaluate uniformity of the plasma shape.

11. The plasma analysis method as claimed in claim 10, wherein evaluating uniformity of the plasma shape in the image comprises evaluating uniformity of the plasma shape based on a distance between a center point of gravity of the plasma shape and an image center point at which the center lines perpendicularly intersect each other.

12. The plasma analysis method as claimed in claim 10, wherein evaluating uniformity of the plasma shape in the image comprises evaluating uniformity of the plasma shape based on ratios of areas of portions of the plasma shape to respective areas of the image divided by the center lines.

13. The plasma analysis method as claimed in claim 8, wherein the optical system adjusts the path of light to allow the camera to capture an image containing a plasma shape in horizontal directions parallel to placement directions of the substrate.

14. The plasma analysis method as claimed in claim 8, wherein the camera comprises a polarizing filter configured to block electromagnetic waves generated from the plasma.

15. An apparatus for processing a substrate using plasma, the apparatus comprising:
a process chamber in which the substrate is processed; and
a plasma analysis device configured to analyze uniformity of plasma formed in the process chamber,
wherein the plasma analysis device comprises:
an optical system configured to adjust a path of light incident thereon from the process chamber;
a camera configured to capture an image of plasma formed in the process chamber; and
an image analyzer configured to analyze a form of the plasma using an image of the plasma captured by the camera,
wherein the camera captures an image containing a plasma shape in horizontal directions parallel to placement directions of the substrate,
wherein the image analyzer evaluates uniformity of the plasma shape in the image, and
wherein the optical system adjusts the path of light to allow the camera to capture an image containing a plasma shape in horizontal directions parallel to placement directions of the substrate.

16. The apparatus as claimed in claim 15, wherein the optical system is implemented as a view port formed in a wall of the process chamber, and
wherein the camera captures the image through the optical system.

17. The apparatus as claimed in claim 15, wherein the image analyzer compares the plasma shape with center lines of the image to evaluate uniformity of the plasma shape.

18. The apparatus as claimed in claim 17, wherein the image analyzer evaluates uniformity of the plasma shape based on a distance between a center point of gravity of the plasma shape and an image center point at which the center lines perpendicularly intersect each other.

19. The apparatus as claimed in claim 17, wherein the image analyzer evaluates uniformity of the plasma shape based on ratios of areas of portions of the plasma shape to respective areas of the image divided by the center lines.

20. The apparatus as claimed in claim 15, wherein the camera comprises a polarizing filter configured to block electromagnetic waves generated from the plasma.
